(19) United States
(12) Patent Application Publication
(10) Pub. No.: US 2012/0224324 A1
(43) Pub. Date: Sep. 6, 2012

(54) ELCTRONIC DEVICE WITH HEAT AND DUST DISSIPATION MECHANISM

(75) Inventor: QIANG YOU, Shenzhen (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/109,007

(22) Filed: May 17, 2011

(30) Foreign Application Priority Data
Mar. 1, 2011 (CN) 201110048771.4

(51) Int. Cl. H05K 7/20

(52) U.S. Cl. 361/692

(57) ABSTRACT

An electronic device includes a housing defining at least one outlet, a number of electronic components accommodated in the housing, at least one fan comprising an intake side and an opposite exhaust side, and a pipe defining a center hole and a number of small holes in the peripheral wall. The pipe includes a number of segments each being mounted adjacent to one of the electronic components. The exhaust side of the fan faces the outlet, and the intake side is coupled to the pipe for communicating with the center hole. When the fan is actuated, heat generated by the electronic components and dust retained within the housing is drawn into the pipe through the small holes and the center hole, and are finally exhausted out of the housing through the at least one outlet.

### BACKGROUND

1. Technical Field

The present disclosure relates to an electronic device with heat and dust dissipation mechanism.

2. Description of Related Art

Generally, a heat sink is often used to dissipate heat generated by the electronic components within an electronic device, e.g., a mobile phone, or a personal computer. However, the heat sink cannot dissipate dust that is retained within the electronic device.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of an electronic device according to an exemplary embodiment.

FIG. 2 is an isometric view of a portion of a pipe of the electronic device of FIG. 1.

### DETAILED DESCRIPTION

Embodiments of the present disclosure are now described in detail, with reference to the accompanying drawings.

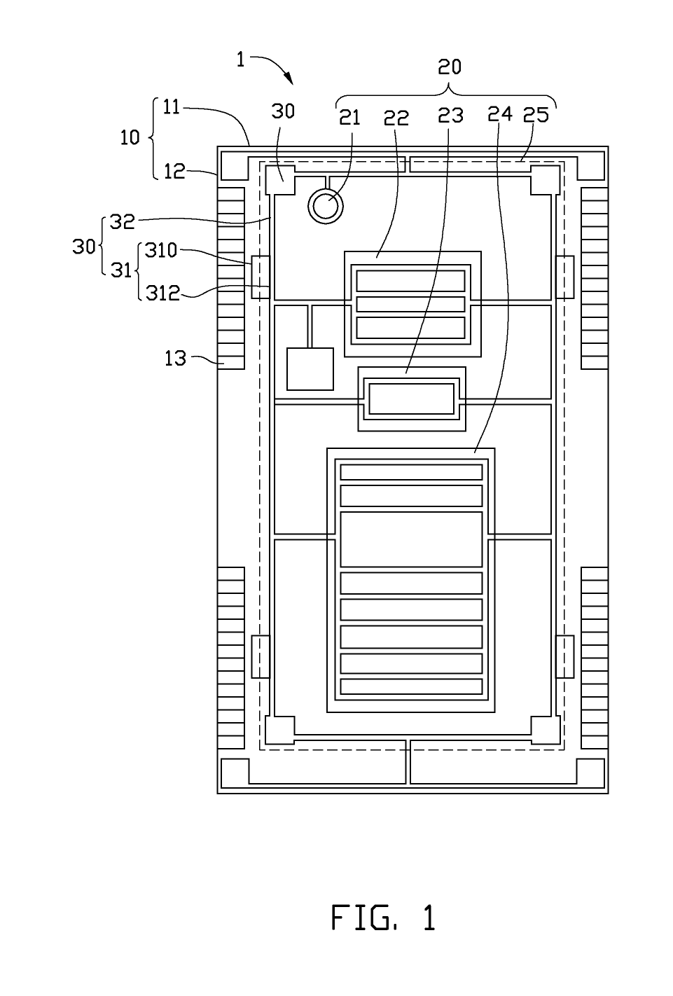

Referring to FIG. 1, an electronic device 1 according to an exemplary embodiment is illustrated. The electronic device 1 includes a housing 10, a number of electronic components 20 accommodated in the housing 10, and a dissipation mechanism 30 for dissipating heat and dust.

The housing 10 is rectangular-shaped and includes two first sides 11 and two second sides 12 extending perpendicularly to the first sides 11. Each second side 12 defines two outlets 13 extending along its longitudinal direction at opposite ends thereof.

The electronic components 20 include a camera 21, a processor 22, a memory 23, an integrated circuit 24, and a display 25. In the embodiment, the memory 23 is a NAND flash memory.

The dissipation mechanism 30 includes four fans 31 and a pipe 32. Each fan 31 includes an intake side 310 and an opposite exhaust side 312. The intake side 310 is configured to intake air into the fan 31, and the exhaust side 312 is configured to exhaust the air out of the fan 31. The fan 31 is correspondingly mounted adjacent to one of the outlets 13 with the exhaust side 312 facing the outlets 13.

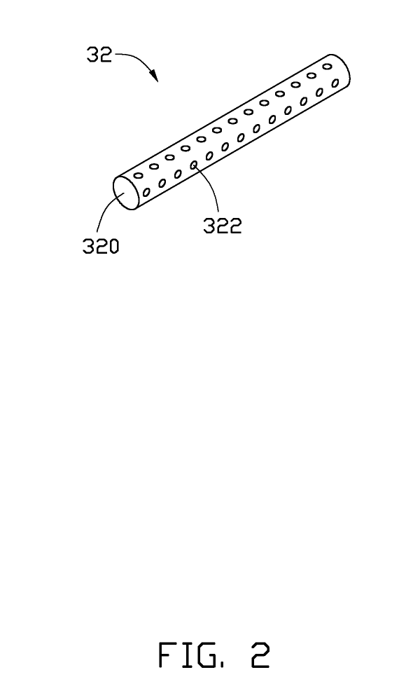

Referring to FIG. 2, a portion of the pipe 32 is illustrated. The pipe 32 defines a center hole 320 and a plurality of small holes 322 in the peripheral wall thereof communicating with the center hole 320. The pipe 32 includes a number of segments each mounted adjacent to one of the electronic components 20. The intake side 310 of each fan 32 is coupled to the pipe 32 and communicates with the center hole 320.

When the fans 31 are actuated, heat generated by the electronic components 20 and dust retained within the housing 10 can be drawn into the pipe 32 through the small holes 322 and the center hole 320, and are finally exhausted out of the housing 10 through the outlets 13.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a housing defining at least one outlet;
a plurality of electronic components accommodated in the housing;
at least one fan each comprising an intake side and an opposite exhaust side, the exhaust side facing one of the at least one outlet; and
a pipe defining a center hole, and a plurality of small holes in the peripheral wall thereof, the pipe comprising a plurality of segments, each segment being mounted adjacent to one of the electronic components, and the intake side of one of the at least one fan coupled to the pipe for communicating with the center hole, wherein when the at least one fan is actuated, heat generated by the electronic components and dust retained within the housing is capable of being drawn into the pipe through the small holes and the center hole, and are finally dispersed out of the housing through the at least one outlet.

2. The electronic device as described in claim 1, wherein the housing comprises two first sides and two second sides extending perpendicularly to the first sides, and the at least one outlet is defined in the second sides.

3. The electronic device as described in claim 1, wherein the electronic components comprises a camera, a processor, a memory, an integrated circuit, and a display.

4. The electronic device as described in claim 3, wherein the memory is a NAND flash memory.
